(19) United States
(12) Patent Application Publication
(10) Pub. No.: US 2017/0334180 A1
(43) Pub. Date: Nov. 23, 2017

(54) RESIN FILM, LAMINATED FILM, OPTICAL MEMBER, DISPLAY MEMBER, FRONT PLATE, AND METHOD FOR PRODUCING LAMINATED FILM

(71) Applicant: SUMITOMO CHEMICAL COMPANY, LIMITED, Tokyo (JP)

(72) Inventors: Satoshi OKAMOTO, Osaka-shi, Osaka (JP); Mitsunori NODONO, Tsukuba-shi, Ibaraki (JP); Takashi SAKURAI, Tsukuba-shi, Ibaraki (JP); Junichi IKEUCHI, Tsukuba-shi, Ibaraki (JP); Mio YASUI, Niihama-shi, Ehime (JP)

(73) Assignee: SUMITOMO CHEMICAL COMPANY, LIMITED, Tokyo (JP)

(21) Appl. No.: 15/525,333

(22) PCT Filed: Nov. 6, 2015
(86) PCT No.: PCT/JP2015/081401

§ 371 Date: May 9, 2017

(30) Foreign Application Priority Data
Nov. 10, 2014 (JP) 2014-228099
Nov. 10, 2014 (JP) 2014-228100
Jul. 22, 2015 (JP) 2015-145176

(51) Int. Cl. B32B 27/28; B32B 27/20; B32B 27/06; H01L 27/32; H01L 51/00; H01L 51/52

(52) U.S. Cl. CPC B32B 27/281; B32B 27/20; B32B 27/06; H01L 51/0097; B32B 2310/0831; B32B 2307/40; H01L 51/524; H01L 2251/5338; H01L 27/323

(57) ABSTRACT

Disclosed is a laminated film including a resin film containing a polyimide-based polymer; and a functional layer provided on at least one principal face side of the resin film. Also disclosed is a resin film containing a polyimide-based polymer and a silicon material containing silicon atoms, in which Si/N that is the atomic ratio between silicon atoms and nitrogen atoms is 8 or greater in at least one principal face.

### TECHNICAL FIELD

The present invention relates to a resin film, a laminated film, an optical member, a display member, a front plate, and a method for producing a laminated film.

### BACKGROUND ART

Glass has been conventionally used as a material for base materials of solar cells or various display members for displays or the like. However, glass has defects such as being easily breakable and being heavy, and also does not necessarily have adequate material characteristics suitable for the trend in thickness reduction, weight reduction and flexisibility of displays in recent years. Therefore, investigations have been conducted on acrylic resins, and laminated films in which resins is provided with scratch resistance, as materials that will substitute glass. Furthermore, investigations have also been conducted on composite materials of organic materials and inorganic materials, such as a hybrid film including polyimide and silica (see, for example, Patent Literatures 1 and 2).

### CITATION LIST

### Patent Literature

Patent Literature 1: Japanese Patent Application Laid-Open Publication No. 2008-163309

Patent Literature 2: U.S. Pat. No. 8,207,256

### SUMMARY OF INVENTION

### Technical Problem

A laminated film having a known acrylic resin as a base material and having a functional layer provided on the base material is not necessarily adequate in view of flexibility to be used as a display member or a front plate for a flexible device.

Thus, an object according to one aspect of the present invention is to provide a laminated film having excellent flexibility.

Furthermore, in order to use a laminated film as a display member or a front plate for a flexible device, the laminated film is also required to have satisfactory visibility upon bending. However, there have been occasions in which even a laminated film having excellent flexibility causes changes in contrast and color upon bending.

Thus, an object according to another aspect of the present invention is to improve visibility upon bending in connection with a laminated film having a functional layer.

In order to use a hybrid film containing a polyimide-based polymer and silica as a flexible member, generally, it is necessary to form functional layers having various functions such as an optical adjustment function and a tacky adhesion function on the hybrid film. However, there have been products in which, when functional layers are formed on a hybrid film, adhesion between the functional layers and the hybrid film is not necessarily sufficient.

Thus, an object according to still another aspect of the present invention is to provide a resin film having excellent adhesiveness to various functional layers, and a laminated film using this resin film.

According to the present invention, an optical member, a display member, and a front plate of flexible devices, all of which use laminated films, are also provided.

### Solution to Problem

A laminated film according to an embodiment of the present invention includes a resin film (resin base material) containing a polyimide-based polymer; and a functional layer provided on at least one principal face side of the resin film.

In regard to the laminated film according to an embodiment of the present invention, the silicon material may be silica particles.

When a light irradiation test of irradiating a laminated film according to an embodiment with light at 313 nm for 24 hours from the functional layer side performed by means of a light source having an output power of 40 W provided at a distance of 5 cm from the laminated film is performed, the laminated film may satisfy the following conditions:

(i) the laminated film after the light irradiation test has a transmittance of 85% or higher for light at 550 nm; and

(ii) the laminated film before the light irradiation test has a degree of yellowness of 5 or less, and the difference between the degrees of yellowness of the laminated film before and after the light irradiation test is less than 2.5. The resin film after the light irradiation test may have a haze of 1.0% or less.

In regard to a laminated film according to an embodiment of the present invention, the functional layer may be a layer having at least one function selected from the group consisting of ultraviolet absorption, surface hardness, tacky adhesiveness, color adjustment, and refractive index adjustment.

In regard to a laminated film according to an embodiment of the present invention, the functional layer may be a layer having at least one function of ultraviolet absorption or surface hardness.

A resin film according to an embodiment of the present invention includes a polyimide-based polymer and a silicon material containing silicon atoms. Si/N that is an atomic ratio between silicon atoms and nitrogen atoms may be 8 or greater in at least one principal face of this resin film. The silicon material may be silica particles.

A laminated film according to an embodiment of the present invention includes a resin film according to an embodiment of the present invention, and a functional layer provided on the principal face side of the resin film where Si/N is 8 or greater.

In regard to a laminated film according to an embodiment of the present invention, a primer layer may be provided between the resin film and the functional layer. The primer layer may contain a silane coupling agent. The silane coupling agent may have at least one substituent selected from the group consisting of a methacryl group, an acryl group, and an amino group.

An optical member according to an embodiment of the present invention includes the laminated film of the present invention. A display member according to an embodiment of the present invention includes a laminated film of the present invention. A front plate according to an embodiment of the present invention includes the laminated film of the present invention.

### Advantageous Effects of Invention

According to the present invention, a laminated film having excellent flexibility can be provided. The laminated film of the present invention can have functions such as transparency, ultraviolet-resistant characteristics and surface hardness, which are required in a case in which the laminated film is applied to an optical member, a display member, or a front plate of a flexible device. According to the present invention, a laminated film having excellent visibility upon bending can be provided.

According to the present invention, a resin film having excellent adhesiveness to various functional layers, a laminated film using the resin film, and a method for producing a laminated film can be provided. The present invention can further provide an optical member, a display member, and a front plate, all of which use a laminated film. The resin film that is obtained by the present invention can have excellent transparency and flexibility.

### BRIEF DESCRIPTION OF DRAWINGS

FIG. 1 is a schematic cross-sectional view illustrating a resin film of a first embodiment.

FIG. 2 is a schematic cross-sectional view illustrating a laminated film of a second embodiment.

FIG. 3 is a schematic cross-sectional view illustrating a laminated film of a third embodiment.

FIG. 4 is a schematic cross-sectional view illustrating an example of a display device.

### DESCRIPTION OF EMBODIMENTS

Hereinafter, embodiments of the present invention will be described in detail. However, the present invention is not limited to the following embodiments.

### First Embodiment

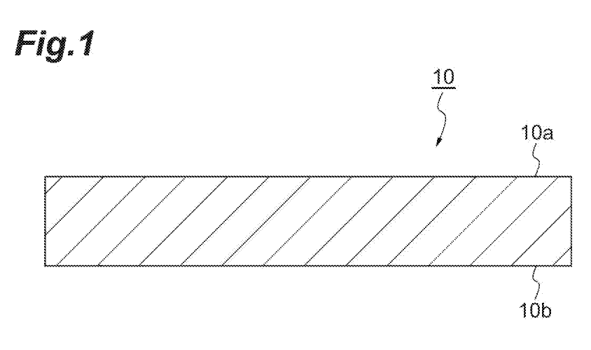

FIG. 1 is a schematic cross-sectional view illustrating a resin film of the present embodiment. The resin film 10 of the present embodiment contains a polyimide-based polymer, and has a pair of principal faces 10a and 10b facing each other.

The polyimide-based polymer included in the resin film 10 may be a polyimide. The polyimide is, for example, a condensed type polyimide that is obtained by condensation polymerization of a diamine and a tetracarboxylic acid dianhydride as starting raw materials. As the polyimide-based polymer, a polymer which is soluble in a solvent used for forming the resin film can be selected.

The diamine is not particularly limited, and aromatic diamines, alicyclic diamines, aliphatic diamines and the like, all of which are usually used for synthesis of polyimides, can be used. Diamines may be used singly, or two or more kinds thereof may be used in combination.

As the tetracarboxylic acid dianhydride, an aromatic tetracarboxylic acid dianhydride, an alicyclic tetracarboxylic acid dianhydride, an acyclic aliphatic tetracarboxylic acid dianhydride, and the like can be used without any particular limitations. Tetracarboxylic acid dianhydrides may be used singly, or two or more kinds thereof may be used in combination. It is also acceptable to use a tetracarboxylic acid compound selected from tetracarboxylic acid compound analogues such as acid chloride compounds, as a starting raw material, instead of the tetracarboxylic acid dianhydride.

At least one of the diamine or the tetracarboxylic acid compound (tetracarboxylic acid dianhydride) may have one or a plurality of at least one functional group selected from the group consisting of a fluorine-based substituent, a hydroxyl group, a sulfone group, a carbonyl group, a heterocyclic ring, and a long-chain alkyl group having 1 to 10 carbon atoms. Among them, from the viewpoint of transparency, the diamine and the tetracarboxylic acid compound may each have a fluorine-based substituent introduced therein as a functional group. The fluorine-based substituent may be any group containing a fluorine atom, and specific examples thereof include a fluorine group (fluorine atom, —F) and a trifluoromethyl group.

From the viewpoints of solubility in a solvent, and transparency and flexibility when the resin film 10 is formed, an alicyclic tetracarboxylic acid compound (alicyclic tetracarboxylic acid dianhydride or the like) or an aromatic tetracarboxylic acid compound (aromatic tetracarboxylic acid dianhydride or the like) can be used as the tetracarboxylic acid compound. From the viewpoint of transparency of the resin film and suppression of coloration, an alicyclic tetracarboxylic acid compound or an aromatic tetracarboxylic acid compound, having a fluorine-based substituent, can be used as the tetracarboxylic acid dianhydride.

As the diamine, an aromatic diamine, an alicyclic diamine or an aliphatic diamine may be used alone, or two or more kinds thereof may be used in combination. From the viewpoints of solubility in a solvent, and transparency and flexibility when the resin film 10 is formed, an alicyclic diamine or an aromatic diamine can be used as the diamine. From the viewpoints of transparency of the resin film and suppression of coloration, an alicyclic diamine or an aromatic diamine, having a fluorine-based substituent, can be used as the diamine.

By using the polyimide-based polymer, a resin film that has particularly excellent flexibility and has a high light transmittance (for example, from 85% or higher, or 88% or higher, for light at 550 nm), a low degree of yellowness (YI value, for example, 5 or lower, or 3 or lower), and a low haze (for example, 1.5% or lower, or 1.0% or lower) is easily obtained.

The polyimide may have a repeating structural unit represented by the following formula (PI). Here, G is a tetravalent organic group, and A is a divalent organic group.

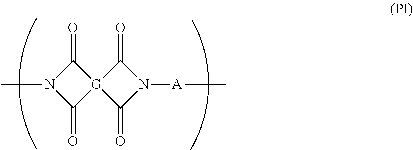

G may be a tetravalent organic group selected from the group consisting of an acyclic aliphatic group, a cyclic aliphatic group, and an aromatic group. G may be a cyclic aliphatic group or an aromatic group. Examples of the aromatic group include a monocyclic aromatic group, a fused polycyclic aromatic group, and a non-fused polycyclic aromatic group having two or more aromatic rings linked to each other directly or via a linking group. From the viewpoints of transparency of the resin film and suppression of coloration, G may be a cyclic aliphatic group, or may be a cyclic aliphatic group, a monocyclic aromatic group, a fused polycyclic aromatic group or a non-fused polycyclic aromatic group, having a fluorine-based substituent. More specific examples include a saturated or unsaturated cycloalkyl group, a saturated or unsaturated heterocycloalkyl group, an aryl group, a heteroaryl group, an arylalkyl group, an alkylaryl group, a heteroalkylaryl group, and a group having any arbitrary two groups (may be identical) among these in which those groups are linked to each other directly or via a linking group. Examples of the linking group include —O—, an alkylene group having 1 to 10 carbon atoms, —SO₂—, —CO—, or —CO—NR— (wherein R represents an alkyl group having 1 to 3 carbon atoms, such as a methyl group, an ethyl group or a propyl group, or a hydrogen atom). The number of carbon atoms of G is typically 2 to 32, and may also be 2 to 27, 5 to 10, 6 to 8, or 3 to 8. In a case in which G is a cyclic aliphatic group or an aromatic group, a part of the carbon atoms may be substituted by heteroatoms. Examples of G include a saturated or unsaturated cycloalkyl group, and a saturated or unsaturated heterocycloalkyl group, and these can have 3 to 8 carbon atoms. Examples of the heteroatoms include O, N, and S.

Specifically, G may be a group represented by the following formula (20), formula (21), formula (22), formula (23), formula (24), formula (25), or formula (26). Symbol * in the formulas represents a bond. Z represents a single bond, —O—, —CH₂—, —C(CH₃)₂—, —Ar—O—Ar—, —Ar—CH₂—Ar—, —Ar—C(CH₃)₂—Ar—, or —Ar—SO₂—Ar—. Ar represents an aryl group having 6 to 20 carbon atoms, and an example thereof is a phenylene group (benzene ring). At least one of the hydrogen atoms in these groups may be substituted with a fluorine-based substituent.

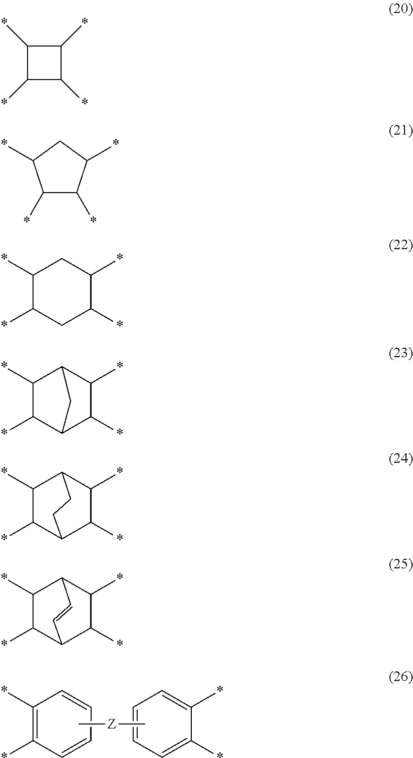

Examples of A include a divalent organic group selected from the group consisting of an acyclic aliphatic group, a cyclic aliphatic group, and an aromatic group. The divalent organic group represented by A may be a cyclic aliphatic group or an aromatic group. Examples of the aromatic group include a monocyclic aromatic group, a fused polycyclic aromatic group, and a non-fused polycyclic aromatic group having two or more aromatic rings linked to each other directly or via a linking group. From the viewpoints of transparency of the resin film and suppression of coloration, a fluorine-based substituent may be introduced into at least a portion of A.

More specific examples of A include a saturated or unsaturated cycloalkyl group, a saturated or unsaturated heterocycloalkyl group, an aryl group, a heteroaryl group, an arylalkyl group, an alkylaryl group, a heteroalkylaryl group, and a group having any arbitrary two groups (may be identical) among these, in which those groups are linked to each other directly or via a linking group. Examples of a heteroatom include O, N, and S. Examples of the linking group include —O—, an alkylene group having 1 to 10 carbon atoms, —SO₂—, —CO—, —CO—NR— (wherein R represents an alkyl group having 1 to 3 carbon atoms, such as a methyl group, an ethyl group or a propyl group, or a hydrogen atom).

The number of carbon atoms of the divalent organic group represented by A is usually 2 to 40, and may also be 5 to 32, 12 to 28, or 24 to 27.

Specifically, A may be a group represented by the following formula (30), formula (31), formula (32), formula (33), or formula (34). Symbol * in the formulas represents a bond. Z¹, Z² and Z³ may each independently represent a single bond, —O—, —CH₂—, —C(CH₃)₂—, —SO₂—, —CO—, or —CO—NR— (wherein R represents an alkyl group having 1 to 3 carbon atoms, such as a methyl group, an ethyl group or a propyl group, or a hydrogen atom). In regard to the groups described below, it is preferable that Z¹ and Z², and Z² and Z³ are respectively at the meta-position or the para-position with respect to each ring. Furthermore, it is preferable that Z¹ and a terminal single bond, Z² and a terminal single bond, and Z³ and a terminal single bond are at the meta-position or the para-position. In an example, Z¹ and Z³ are each —O—, and Z² is —CH₂—, —C(CH₃)₂—, or —SO₂—. At least one of hydrogen atoms of these groups may be substituted with a fluorine-based substituent.

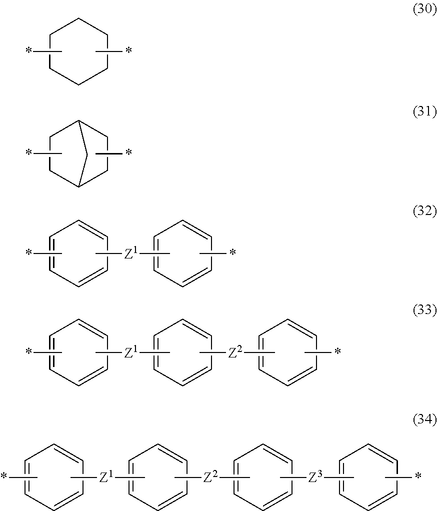

In at least one of A or G, at least one hydrogen atom may be substituted with at least one functional group selected from the group consisting of a fluorine-based substituent containing a fluorine atom, such as a fluorine group and a trifluoromethyl group, a hydroxyl group, a sulfone group, an alkyl group having 1 to 10 carbon atoms, and the like. In a case in which A and G are each a cyclic aliphatic group or an aromatic group, at least one of the A or G may have a fluorine-based substituent, or both of A and G may have a fluorine-based substituent.

The polyimide-based polymer may be a polymer containing at least one repeating structural unit represented by formula (PI), formula (a), formula (a′), or formula (b). G² in formula (a) represents a trivalent organic group, and A² represents a divalent organic group. G³ in formula (a′) represents a tetravalent organic group, and A³ represents a divalent organic group. G⁴ and A⁴ in formula (b) each represent a divalent organic group.

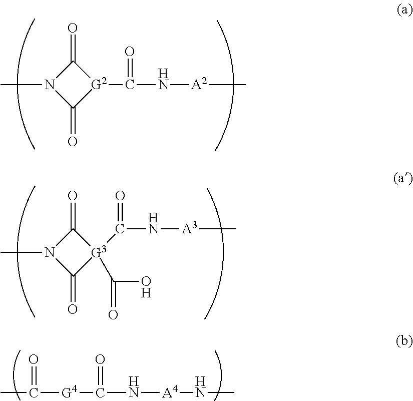

Except for being a trivalent group, G² in formula (a) can be selected from groups similar to G in formula (PI). For example, G² may be a group in which any one of the four bonds in each of the groups represented by formula (20) to formula (26) exemplified as specific examples of G is substituted with a hydrogen atom. A² in formula (a) can be selected from groups similar to A in formula (PI).

G³ in formula (a′) can be selected from groups similar to G in formula (PI). A³ in formula (a′) can be selected from groups similar to A in formula (PI).

Except for being a divalent group, G⁴ in Formula (b) can be selected from groups similar to G in formula (PI). For example, G⁴ may be a group in which any two of the four bonds in each of the groups represented by formula (20) to formula (26) exemplified as specific examples of G are substituted with hydrogen atoms. A⁴ in formula (b) can be selected from groups similar to A in formula (PI).

The polyimide-based polymer that is a polymer containing at least one repeating structural unit represented by formula (PI), formula (a), formula (a′), or formula (b) may be a condensed type polymer obtainable by polycondensing a diamine and at least one of a tetracarboxylic acid compound or a tricarboxylic acid compound (including tricarboxylic acid compound analogues such as acid chloride compounds and tricarboxylic acid anhydrides). As the starting raw materials, in addition to these, a dicarboxylic acid compound (including analogues such as acid chloride compounds) may also be used. The repeating structural unit represented by formula (a′) is typically derived from a diamine and a tetracarboxylic acid compound. The repeating structural unit represented by formula (a) is typically derived from a diamine and a tricarboxylic acid compound. The repeating structural unit represented by formula (b) is typically derived from a diamine and a dicarboxylic acid compound. Specific examples of the diamine and the tetracarboxylic acid compound are as described above.

Examples of the tricarboxylic acid compound include an aromatic tricarboxylic acid, an alicyclic tricarboxylic acid, an acyclic aliphatic tricarboxylic acid, and acid chloride compounds and acid anhydrides, which are analogues of those acids. The tricarboxylic acid compound may be an aromatic tricarboxylic acid, an alicyclic tricarboxylic acid, an acyclic aliphatic tricarboxylic acid, or an acid chloride compound, which is an analogous compound of those. Two or more kinds the tricarboxylic acid compound may be used in combination.

From the viewpoints of solubility in a solvent, and transparency and flexibility when the resin film 10 is formed, the tricarboxylic acid compound can be selected from an alicyclic tricarboxylic acid compound and an aromatic tricarboxylic acid compound. From the viewpoints of transparency of the resin film and suppression of coloration, the tricarboxylic acid compound may include an alicyclic tricarboxylic acid compound having a fluorine-based substituent and an aromatic tricarboxylic acid compound having a fluorine-based substituent.

Examples of the dicarboxylic acid compound include an aromatic dicarboxylic acid, an alicyclic dicarboxylic acid, an acyclic aliphatic dicarboxylic acid, and acid chloride compounds and acid anhydrides, which are analogues thereof. The dicarboxylic acid compound may be an aromatic dicarboxylic acid, an alicyclic dicarboxylic acid, an acyclic aliphatic dicarboxylic acid, or an acid chloride compound, which is an analogous compound of those. Two or more kinds of the dicarboxylic acid compound may be used in combination.

From the viewpoints of solubility in a solvent, and transparency and flexibility the resin film 10 is formed, the dicarboxylic acid compound can be selected from an alicyclic dicarboxylic acid compound and an aromatic dicarboxylic acid compound. From the viewpoints of transparency of the resin film and suppression of coloration, the dicarboxylic acid compound can be selected from an alicyclic dicarboxylic acid compound having a fluorine-based substituent, and an aromatic dicarboxylic acid compound having a fluorine-based substituent.

The polyimide-based polymer may be a copolymer including a plurality of the above-mentioned repeating units of different kinds. The weight averaged molecular weight of the polyimide-based polymer is typically 10,000 to 500,000. The weight averaged molecular weight of the polyimide-based polymer may also be 50,000 to 500,000, 100,000 to 500,000, or 70,000 to 400,000. The weight averaged molecular weight is a molecular weight converted into polystyrene standards measured by GPC. When the weight averaged molecular weight of the polyimide-based polymer is larger, there is a tendency that high flexibility is easily obtained. If the weight average molecular weight of the polyimide-based polymer is too large, the viscosity of a varnish increases, and processability tends to decrease.

The polyimide-based polymer may contain a halogen atom such as a fluorine atom, which can be introduced by the fluorine-based substituent or the like as described above. When the polyimide-based polymer contains a halogen atom, the elastic modulus of the resin film can be increased, and the degree of yellowness can be decreased. Thereby, scratches, wrinkles and the like occurring in the resin film are suppressed, and transparency of the resin film can be enhanced. For example, a fluorine atom can be introduced into a molecule of polyimide (polyimide-based polymer) by using a compound having a fluorine-based substituent such as a fluorine group or a trifluoromethyl group as at least one of the diamine or the tetracarboxylic acid dianhydride. The content of the halogen atom (or fluorine atom) in the polyimide may be 1% by mass to 40% by mass, or 1% by mass to 30% by mass, based on the mass of the polyimide-based polymer.

The resin film 10 may further contain an inorganic material such as inorganic particles. The inorganic material may be a silicon material containing silicon atoms. When the resin film 10 contains an inorganic material such as a silicon material, particularly excellent effects in view of flexibility can be obtained.

Examples of the silicon material containing silicon atoms include silica particles, and silicon compounds such as quaternary alkoxysilanes such as tetraethyl orthosilicate (TEOS). The silicon material may also be silica particles, from the viewpoints of transparency and flexibility of the resin film 10.

The average primary particle size of the silica particles may be 10 nm to 100 nm, or 20 nm to 80 nm. When the average primary particle size of the silica particles is 100 nm or less, transparency tends to increase. When the average primary particle size of the silica particles is 10 nm or more, there is a tendency that strength of the resin film is increased, and there is a tendency that the cohesive force of the silica particles becomes weak, and therefore, handling becomes easier.

The (averaged) primary particle size of the silica particles in the resin film can be determined by observation by transmission electron microscopy (TEM). The particle size distribution of the silica particles before the resin film is formed can be determined by a commercially available laser diffraction type particle size distribution analyzer.

In regard to the resin film 10, the mixing ratio between the polyimide and the inorganic material (silicon material) may be, as a mass ratio, 1:9 to 10:0 or 1:9 to 9:1, or may be 3:7 to 10:0 or 3:7 to 8:2. This mixing ratio may also be 3:7 to 8:2 or 3:7 to 7:3. The proportion of the inorganic material with respect to the total mass of the polyimide and the inorganic material is typically 20% by mass or more, and may also be 30% by mass or more. This proportion is typically 90% by mass or less, and may also be 70% by mass or less. When the mixing ratio between the polyimide and the inorganic material (silicon material) is within the range described above, transparency and mechanical strength of the resin film tend to increase.

The resin film 10 may further contain components other than the polyimide and the inorganic material (silicon material), to the extent that transparency and flexibility are not noticeably impaired. Examples of the component other than the polyimide and the inorganic material (silicon material) include an oxidation inhibitor, a mold release agent, a stabilizer, a bluing agent, a flame retardant, a lubricating agent, and a leveling agent. The total proportion of the polyimide and the inorganic material may be more than 0% to 20% by mass or less, or may be more than 0% to 10% by mass or less, with respect to the mass of the resin film 10.

When the resin film 10 contains a polyimide and a silicon material, Si/N that is an atomic ratio of silicon atoms with respect to nitrogen atoms, in at least one principal face 10a may be 8 or greater. This atomic ratio Si/N is a value obtained by evaluating the composition of the principal face 10a by X-ray photoelectron spectroscopy (XPS), and calculating the value from the abundance of silicon atoms and the abundance of nitrogen atom obtained by this evaluation.

When Si/N in a principal face 10a of the resin film 10 is 8 or greater, sufficient adhesiveness to the functional layer 20 that will be described later is obtained. From the viewpoint of adhesiveness, Si/N may be 9 or higher, or 10 or higher. Si/N is typically 50 or lower, and may be 40 or lower.

The thickness of the resin film 10 is appropriately adjusted depending on the flexible device to which the laminated film 30 is applied; however, the thickness may be 10 μm to 500 μm, 15 μm to 200 μm, or 20 μm to 100 μm. A resin film 10 having such a configuration can have particularly excellent flexibility.

Next, an example of a method for producing the resin film 10 of the present embodiment will be described.

A solvent-soluble polyimide that has been polymerized by using a known synthesis technique for polyimide is dissolved in a solvent, and a polyimide varnish is prepared. The solvent may be any solvent that dissolves polyimide, and examples include N,N-dimethylacetamide (DMAc), N,N-dimethylformamide (DMF), dimethyl sulfoxide (DMSO), γ-butyrolactone (GBL), and combinations thereof (mixed solvents).

In a case in which a resin film containing an inorganic material (silicon material) is produced, subsequently, an inorganic material is added to the polyimide-based polymer varnish, and the mixture is stirred and mixed by a known stirring method. Thus, a dispersion liquid in which the silicon material is uniformly dispersed is prepared.

The mixing ratio between the polyimide and the inorganic material in the polyimide-based polymer varnish or the dispersion liquid may be, as a mass ratio, 1:9 to 9:1, or 3:7 to 8:2.

The polyimide-based polymer varnish or the dispersion liquid may further include additives. The additives are selected from, for example, an oxidation inhibitor, a mold release agent, a stabilizer, a bluing agent, a flame retardant, a lubricating agent, and a leveling agent. The polyimide-based polymer varnish or the dispersion liquid may include a compound such as an alkoxysilane having one or two or more metal alkoxide groups, which contributes to bond forming between inorganic particles (silica particles or the like). When a dispersion liquid including such a compound is used, the mixing proportion of the inorganic particles can be made large while the optical characteristics such as transparency of the resin film are maintained. Examples of such a compound include an alkoxysilane having an amino group.

Next, the dispersion liquid is applied on a base material by, for example, a known roll-to-roll or batch system, to form a coating film. The coating film is dried, and thus a film is formed. Subsequently, the film is peeled off from the base material, and thereby a resin film 10 is obtained. The base material may be, for example, a polyethylene terephthalate (PET) base material, a SUS belt, or a glass base material.

For drying and/or baking of the coating film, the coating film may be heated. The coating film can be heated at a temperature of 50° C. to 350° C. in an inert atmosphere or under reduced pressure conditions, as appropriate. The solvent can be evaporated by heating the coating film. A resin film may also be formed by a method including drying the coating film at 50° C. to 150° C., and baking the coating film after drying at 180° C. to 350° C.

Next, at least one principal face of the resin film may be subjected to a surface treatment. The surface treatment may be a UV ozone treatment. Si/N can be easily adjusted to be 8 or greater by a UV ozone treatment. However, the method for adjusting Si/N to be 8 or greater is not limited to the UV ozone treatment. The principal faces 10a and/or 10b of the resin film 10 may be subjected to a surface treatment such as a plasma treatment or a corona discharge treatment, in order to enhance adhesiveness to the functional layer that will be described below.

The UV ozone treatment can be carried out by using a known ultraviolet light source including a wavelength of 200 nm or less. An example of the ultraviolet light source may be a low pressure mercury lamp. As the ultraviolet light source, various commercially available apparatuses equipped with an ultraviolet light source may also be used. An example of the commercially available apparatuses may be an ultraviolet (UV) ozone cleaning apparatus, UV-208, manufactured by Technovision, Inc.

The resin film 10 of the present embodiment that is obtained as such has excellent flexibility. Furthermore, when Si/N, which is an atomic ratio between silicon atoms and nitrogen atoms, for at least one principal face 10a is adjusted to be 8 or greater, excellent adhesiveness to the functional layer 20 that will be described below is obtained.

### Second Embodiment

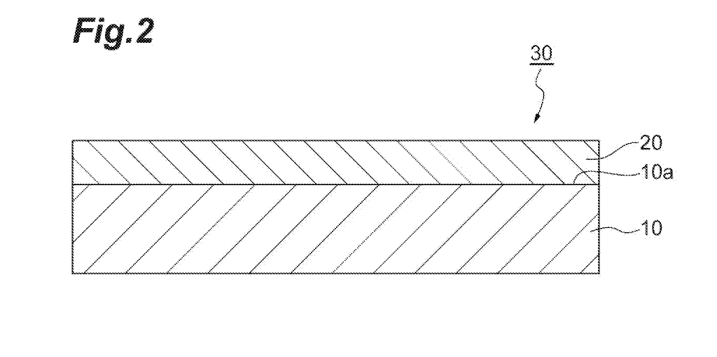

Hereinafter, a laminated film according to a second embodiment will be described with reference to FIG. 2.

FIG. 2 is a schematic cross-sectional diagram illustrating a laminated film of the present embodiment. In FIG. 2, the same reference numeral will be assigned to a constituent element that is identical with the resin film of the first embodiment illustrated in FIG. 1, and a description thereon will be omitted.

A laminated film 30 of the present embodiment is generally configured to include a resin film 10, and a functional layer 20 that is laminated on one principal face 10a of the resin film 10.

The functional layer 20 may be a layer intended for further imparting a function (performance) to the laminated film 30 when the laminated film 30 is used as an optical member, a display member, or a front plate of a flexible device. The functional layer 20 may be a layer having at least one function selected from the group consisting of ultraviolet absorption, surface hardness, tacky adhesiveness, color adjustment, and refractive index adjustment.

A layer having a function of ultraviolet absorption (ultraviolet absorbing layer) as the functional layer 20 is configured to include, for example, a main material selected from an ultraviolet-curable type transparent resin, an electron beam-curable type transparent resin, and a thermosetting type transparent resin; and an ultraviolet absorber dispersed in this main material. By providing an ultraviolet absorbing layer as the functional layer 20, a change in the degree of yellowness caused by light irradiation can be easily suppressed.

The ultraviolet-curable type, electron beam-curable type, or thermosetting type transparent resin as a main material of the ultraviolet absorbing layer is not particularly limited; however, for example, the transparent resin may be poly(meth)acrylate.

The ultraviolet absorber may include at least one compound selected from the group consisting of, for example, a benzophenone-based compound, a salicylate-based compound, a benzotriazole-based compound, and a triazine-based compound.

According to the present specification, a “-based compound” refers to a derivative of a compound to which this “-based compound” is attached. For example, a “benzophenone-based compound” refers to a compound having benzophenone as a mother skeleton and a substituent that is bonded to the benzophenone. This is also the same for other “-based compounds”.

The ultraviolet absorbing layer may be a layer which absorbs 95% or more of light having a wavelength of 400 nm or less (for example, light having a wavelength of 313 nm). In other words, the ultraviolet absorbing layer may be a layer in which the transmittance for light having a wavelength of 400 nm or less (for example, light having a wavelength of 313 nm) is less than 5%. The ultraviolet absorbing layer can include an ultraviolet absorber at a concentration at which such a transmittance can be obtained. From the viewpoint of suppressing an increase in the degree of yellowness of the laminated film caused by light irradiation, the proportion of the ultraviolet absorber in the ultraviolet absorbing layer (functional layer 20) is typically 1% by mass or more, and may also be 3% by mass or more, based on the mass of the ultraviolet absorbing layer. This proportion is typically 10% by mass or less, and may also be 8% by mass or less.

A layer (hard coat layer) having a function of surface hardness (function by which high hardness is exhibited at the surface) as the functional layer 20 is, for example, a layer that provides a surface having higher pencil hardness than the pencil hardness of the surface of a resin film, to the laminated film. The pencil hardness of the surface of the hard coat layer may be, for example, 2 H or higher. This hard coat layer is not particularly limited, but includes an ultraviolet-curable type, electron beam-curable type, or thermosetting type resin, which is represented by a poly(meth)acrylate. The hard coat layer may also include a photopolymerization initiator and an organic solvent. The poly(meth)acrylate is a poly(meth)acrylate which is formed from one or more (meth)acrylates selected from a polyurethane (meth)acrylate, an epoxy (meth)acrylate, and other polyfunctional poly(meth)acrylates, and includes monomer units derived from these monomers. The hard coat layer may also include silica, alumina or an inorganic acid compound such as a polyorganosiloxane, in addition to the components described above.

A layer having a function of tacky adhesiveness (tacky adhesive layer) as the functional layer 20 has a function of adhering the laminated film 30 to another member. As the material for forming the tacky adhesive layer, a material that is conventionally known can be used. For example, a thermosetting resin composition or a photocurable resin composition can be used.

The tacky adhesive layer may be formed from a resin composition that includes a component having a polymerizable functional group. In this case, strong adhesion can be realized by adhering the laminated film 30 to another member, and then further polymerizing the resin composition that constitute the tacky adhesive layer. The adhesive strength between the resin film 10 and the tacky adhesive layer may be 0.1 N/cm or more, or 0.5 N/cm or more.

The pressure-sensitive adhesive layer may include a thermosetting resin composition or a photocurable resin composition as a material. In this case, the resin composition can be cured by converting the resin composition into a polymer by supplying energy afterwards.

The tacky adhesive layer may be a layer that is stuck to an object by pressing, which is called a pressure-sensitive adhesive (PSA). The pressure-sensitive adhesive may be a tacky adhesive which is “a substance that has tacky adhesiveness at normal temperature and adheres to an adherend material under light pressure” (JIS K6800), or may be a capsule type adhesive which is “an adhesive that internally contains a particular component in a protective coating film (microcapsule) and retains stability until the coating film is destroyed by an appropriate means (pressure, heat or the like)” (JIS K6800).

A layer having a function of color adjustment (color adjusting layer) as the functional layer 20 is a layer with which the laminated film 30 can be adjusted to an intended color. The color adjusting layer is, for example, a layer containing a resin and a colorant. Examples of this colorant include inorganic pigments such as titanium oxide, zinc oxide, colcothar, a titanium oxide-based calcined pigment, ultramarine blue, cobalt aluminate, and carbon black; organic pigments such as an azo-based compound, a quinacridone-based compound, an anthraquinone-based compound, a perylene-based compound, an isoindolinone-based compound, a phthalocyanine-based compound, a quinophthalone-based compound, an indanthrene-based compound, and a diketopyrrolopyrrole-based compound; extender pigments such as barium sulfate and calcium carbonate; and dyes such as a basic dye, an acidic dye, and a mordant dye.

A layer having a function of refractive index adjustment (refractive index adjusting layer) as the functional layer 20 is a layer which has a refractive index that is different from that of the resin film 10, and can impart a predetermined refractive index to the laminated film. The refractive index adjusting layer may be, for example, a resin layer containing an appropriately selected resin and optionally further containing a pigment, or may be a thin film of a metal.

Examples of the pigment that adjusts the refractive index include silicon oxide, aluminum oxide, antimony oxide, tin oxide, titanium oxide, zirconium oxide, and tantalum oxide. The averaged particle size of the pigment may be 0.1 μm or less. By adjusting the average particle size of the pigment to 0.1 μm or less, diffusion reflection of light that is transmitted through the refractive index layer is prevented, and a decrease in the degree of transparency can be prevented.

Examples of the metal that is used for the refractive index adjusting layer include metal oxides or metal nitrides, such as titanium oxide, tantalum oxide, zirconium oxide, zinc oxide, tin oxide, silicon oxide, indium oxide, titanium oxynitride, titanium nitride, silicon oxynitride, and silicon nitride.

The functional layer 20 has the above-described functions as appropriate according to the use of the laminated film 30. The functional layer 20 may be a single layer, or may be a plurality of layers. Each layer may have one function or two or more functions.

The functional layer 20 may have functions of surface hardness and ultraviolet absorption. The functional layer 20 in this case may include “a single layer having functions of surface hardness and ultraviolet absorption”, “a multilayer including a layer having surface hardness and a layer having ultraviolet absorption”, or “a multilayer including a single layer having functions of surface hardness and ultraviolet absorption and a layer having surface hardness”.

The thickness of the functional layer 20 is appropriately adjusted according to the flexible device to which the laminated film 30 is applied; however, the thickness may be, for example, 1 μm to 100 μm, or 2 μm to 80 μm. The functional layer 20 is typically thinner than the resin film 10.

The laminated film 30 can be obtained by forming the functional layer 20 on a principal face 10a of the resin film 10. The functional layer 20 can be formed by a known roll-to-roll or batch system.

An ultraviolet absorbing layer as the functional layer 20 can be formed by, for example, a method of applying a dispersion liquid including main materials such as an ultraviolet absorber and a resin in which the ultraviolet absorber is dispersed, on a principal face 10a of a resin film 10, thereby forming a coating film, and drying and curing the coating film.

A hard coat layer as the functional layer 20 can be formed by, for example, a method of applying a solution including a resin that forms a hard coat layer, on a principal face 10a of a resin film 10, thereby forming a coating film, and drying and curing the coating film.

A tacky adhesive layer as the functional layer 20 can be formed by, for example, a method of applying a solution including a tacky adhesive that forms a tacky adhesive layer, on a principal face 10a of a resin film 10, thereby forming a coating film, and drying and curing the coating film.

A color adjusting layer as the functional layer 20 can be formed by, for example, a method of applying a dispersion liquid including main materials such as a pigment that forms a color adjusting layer, and a resin in which the pigment and the like are dispersed, on a principal face 10a of a resin film 10, thereby forming a coating film, and drying and curing the coating film.

A refractive index layer adjusting layer as the functional layer 20 can be formed by, for example, a method of applying a dispersion liquid including main materials such as inorganic particles that form a refractive index layer, and a resin in which the inorganic particles and the like are dispersed, on a principal face 10a of a resin film 10, thereby forming a coating film, and drying and curing the coating film.

A single layer having functions of surface hardness and ultraviolet absorption as the functional layer 20 can be formed by a method of applying a dispersion liquid including main materials such as an ultraviolet absorber and a resin in which the ultraviolet absorber is dispersed, and a resin that forms a hard coat layer, on a principal face 10a of a resin film 10, thereby forming a coating film, and drying and curing the coating film. The resin of the main materials and the resin that forms a hard coat layer may be the same.

It is also acceptable that an ultraviolet absorbing layer is formed by applying a dispersion liquid including main materials such as an ultraviolet absorber and a resin which the ultraviolet absorber is dispersed, on a principal face 10a of a resin film 10, thereby forming a coating film, and drying and curing the coating film; and then a hard coat layer is formed on the ultraviolet absorbing layer by applying a solution including a resin that forms a hard coat layer, thereby forming a coating film, and drying and curing the coating film. Multiple functional layers including a layer having surface hardness and a layer having ultraviolet absorption are formed by this method.

It is also acceptable that a single layer having functions of surface hardness and ultraviolet absorption is formed by applying a dispersion liquid including main materials such as an ultraviolet absorber and a resin in which the ultraviolet absorber is dispersed, and a resin that forms a hard coat layer, on a principal face 10a of a resin film 10, thereby forming a coating film, and drying and curing the coating film; and a hard coat layer is further formed on the single layer by applying a solution including a resin that forms a hard coat layer, thereby forming a coating film, and drying and curing the coating film. Multiple functional layers including a layer having functions of surface hardness and ultraviolet absorption and a layer having surface hardness are formed by this method.

A laminated film 30 of the present embodiment that is obtained as such has excellent flexibility. The laminated film 30 can have functional properties such as transparency, ultraviolet-resistant characteristics, and surface hardness, which are required in a case in which the laminated film 30 is applied to an optical member, a display member or a front plate of a flexible device. In a case in which Si/N at a principal face 10a of the resin film 10 is 8 or greater, the adhesiveness between the resin film 10 and the functional layer 20 is also excellent.

When a light irradiation test of irradiating a laminated film 30 with light at 313 nm for 24 hours from the functional layer 20 side by a light source that is provided at a distance of 5 cm from the laminated film 30 and has an output power of 40 W is performed, the laminated film 30 may satisfy the following conditions:

(i) the laminated film after the light irradiation test has a transmittance of 85% or higher for light at 550 nm, and a haze of 1.0% or less; and

(ii) the laminated film before the light irradiation test has a degree of yellowness (YI value) of 5 or less, and the difference between the degrees of yellowness of the laminated film before and after the light irradiation test is less than 2.5. A laminated film that satisfies these conditions (i) and (ii), does not easily undergo a change in contrast or color upon bending, and can maintain satisfactory visibility.

For example, when a layer having a function of ultraviolet absorption is provided as a functional layer 20, and a layer having a transmittance of 85% or higher for light at 550 nm and a haze of 1.0% or less is used as a resin film 10 and a functional layer 20, a laminated film that satisfies the conditions (i) and (ii) can be easily obtained.

The transmittance for light at 550 nm of the laminated film after the light irradiation test may be 90% or higher, and may be 100% or lower, or 95% or lower. The haze of the laminated film after the light irradiation test may be 0.9 or less, or 0.1 or higher. The laminated film before the light irradiation test may have a transmittance of 85% or higher for light at 550 nm and a haze value of 1.0 or less. The details of the method for measuring transmittance and haze will be described in the Examples that will be described below.

The degree of yellowness of the laminated film before the light irradiation test may be 4 or less, or 3 or less, and may be 0.5 or higher. When the degree of yellowness before the light irradiation test is designated as YI₀, and the degree of yellowness after the light irradiation is YI₁, the difference between the degrees of yellowness of the laminated film before and after the light irradiation test, ΔYI, is calculated by formula: ΔYI=YI₁−YI₀. ΔYI is preferably 2.2 or less, may be 2.0 or less, and may be 0.1 or greater. The details of the method for measuring the degree of yellowness will be described in the Examples that are described below.

In the present embodiment, a configuration in which the functional layer 20 is laminated on one principal face 10a of the resin film 10 has been described as an example; however, the present invention is not limited to those. For example, a functional layer may be laminated on both surfaces of a resin film.

The laminated film 30 of the present embodiment is used as, for example, an optical member, a display member, or a front plate of a flexible device.

### Third Embodiment

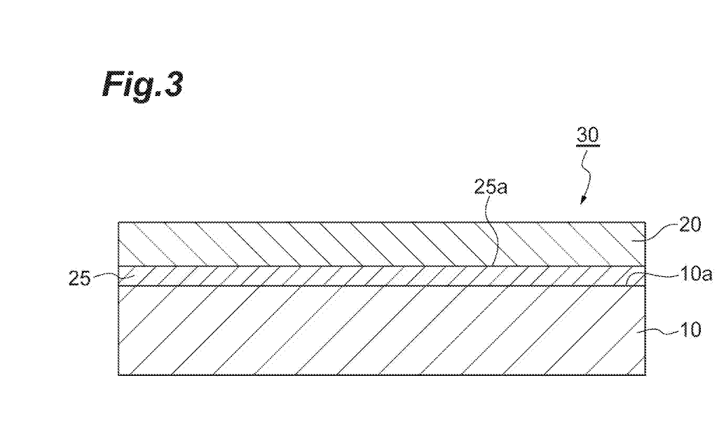

Hereinafter, a laminated film according to a third embodiment will be described with reference to FIG. 3.

FIG. 3 is a schematic cross-sectional view illustrating a laminated film of the present embodiment. In FIG. 3, the same reference numeral will be assigned to a constituent element that is identical or equivalent to the laminated film of the second embodiment illustrated in FIG. 2, and a description thereon will be omitted. A laminated film 30 of the present embodiment is generally configured to include a resin film 10; a functional layer 20 provided on one principal face 10a side of the resin film; and a primer layer 25 provided between the resin film 10 and the functional layer 20. The primer layer 25 is laminated on one principal face 10a of the resin film 10. The functional layer 20 is laminated on a principal face on the opposite side of the principal face of the primer layer 25 that is in contact with the resin film 10 (hereinafter, may be referred to as “one principal face”) 25a.

The primer layer 25 is a layer formed from a primer agent, and it is preferable that the primer layer 25 includes a material that can increase adhesiveness to the resin film 10 and the functional layer 20. The compound included in the primer layer 25 may be chemically bonded to the interface with the polyimide-based polymer, the silicon material or the like included in the resin film 10.

Examples of the primer agent include primer agents of ultraviolet-curable type, thermosetting type, or two-liquid curable type epoxy-based compounds. The primer agent may be a polyamic acid. These are suitable for increasing adhesiveness to the resin film 10 and the functional layer 20.

The primer agent may include a silane coupling agent. The silane coupling agent may be chemically bonded to the silicon material that is included in the resin film, by a condensation reaction. The silane coupling agent is particularly useful in a case in which particularly the mixing ratio of the silicon material included in the resin film 10 is high.

A silane coupling agent is a compound having an alkoxysilyl group, which has a silicon atom; and one to three alkoxy groups that are covalently bonded to the silicon atom. The silane coupling agent may be a compound including a structure in which two or more alkoxy groups are covalently bonded to a silicon atom, or a compound including a structure in which three alkoxy groups are covalently bonded to a silicon atom. Examples of the alkoxy group include a methoxy group, an ethoxy group, an isopropoxy group, a n-butoxy group, and a t-butoxy group. Among them, a methoxy group and an ethoxy group can increase the reactivity with a silicon material.

The silane coupling agent can have a substituent having high affinity to the resin film 10 and the functional layer 20. From the viewpoint of affinity with the polyimide-based polymer included in the resin film 10, the substituent of the silane coupling agent may be an epoxy group, an amino group, an ureido group, or an isocyanate group. In a case in which the functional layer 20 includes a (meth)acrylate, if the silane coupling agent used for the primer layer 25 has an epoxy group, a methacryl group, an acryl group, an amino group, or a styryl group, affinity tends to increase. Among these, a silane coupling agent having a substituent selected from a methacryl group, an acryl group and an amino group exhibits a tendency of having excellent affinity to the resin film 10 and the functional layer 20.

The thickness of the primer layer 25 is appropriately adjusted according to the functional layer 20; however, the thickness may be 0.01 nm to 20 μm. In the case of using a primer agent of an epoxy-based compound, the thickness of the primer layer 25 may be 0.01 μm to 20 μm, or 0.1 μm to 10 μm. In the case of using a silane coupling agent, the thickness of the primer layer 25 may be 0.1 nm to 1 μm, or 0.5 nm to 0.1 μm.

Next, a method for producing the laminated film 30 of FIG. 3 of the present embodiment will be described.

First, a resin film 10 is produced in the same manner as in the first embodiment. Next, a solution obtained by dissolving a primer agent is applied on one principal face 10a of the resin film 10 by a known roll-to-roll or batch system, and thus a first coating film is formed. The first coating film may be slightly cured, if necessary.

Next, a raw material of the functional layer 20 is applied on the first coating film in the same manner as in the first embodiment, and thus a second coating film is formed. A primer layer 25 and a functional layer 20 are formed by curing the first coating film and the second coating film simultaneously or separately, and a laminated film 30 is obtained.

The laminated film 30 of the present embodiment that is obtained as such has excellent flexibility. Since the primer layer 25 is provided between the resin film 10 and the functional layer 20, the adhesiveness of the functional layer 20 to the resin film 10 is high. The laminated film 30 can have functional properties such as transparency, ultraviolet-resistant characteristics, and surface hardness, which are required in a case in which the laminated film 30 is applied to an optical member, a display member, and a front plate of flexible devices.

In the present embodiment, the case in which a functional layer 20 is provided on one principal face 10a side of a resin film 10, and a primer layer 25 is provided between the resin film 10 and the functional layer 20, has been illustrated as an example; however, the present invention is not limited to this. A functional layer may also be laminated on both sides of the resin film, with a primer layer being disposed therebetween.

### Fourth Embodiment

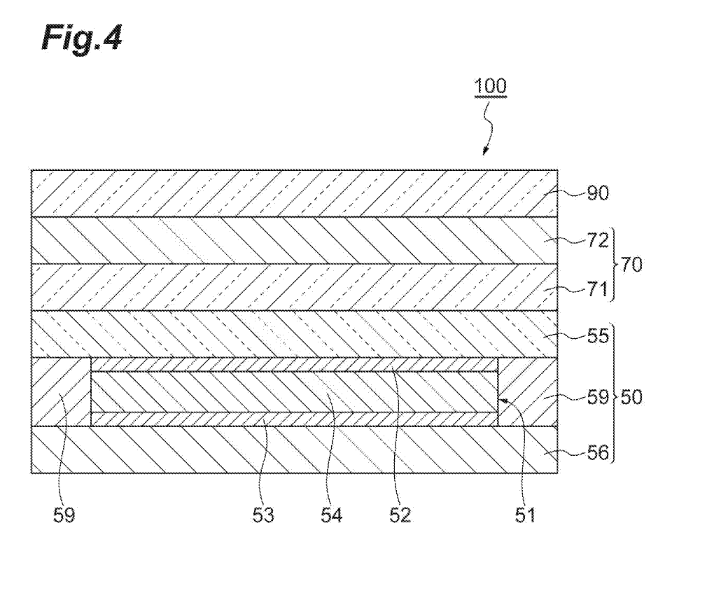

Hereinafter, a display device according to a fourth embodiment will be described using FIG. 4.

FIG. 4 is a schematic cross-sectional view illustrating an example of a display device, which is an application example of the laminated film of the present embodiment. The display device 100 of the present embodiment has an organic EL device 50; a touch sensor 70; and a front plate 90. These are usually accommodated in a housing. The gap between the organic EL device 50 and the touch sensor 70, and the touch sensor 70 and the front plate 90 are adhered with, for example, an optical clear adhesive (OCA).

The organic EL device 50 has an organic EL element 51; a first substrate 55; a second substrate 56; and a sealing material 59.

The organic EL element 51 has a pair of electrodes (first electrode 52 and a second electrode 53), and a light emitting layer 54. The light emitting layer 54 is disposed between the first electrode 52 and the second electrode 53.

The first electrode 52 is formed by means of an electrically conductive material having light transmissibility. The second electrode 53 may also have light transmissibility. Regarding the first electrode 52 and the second electrode 53, known materials can be employed.

The light emitting layer 54 can be formed by means of a known light emitting material that constitutes an organic EL element. The light emitting material may be any of a low molecular weight compound and a high molecular weight compound.

When electric power is supplied between the first electrode 52 and the second electrode 53, carriers (electrons and holes) are supplied to the light emitting layer 54, and light is generated in the light emitting layer 54. The light generated in the light emitting layer 54 is emitted to the outside of the organic EL device 50 through the first electrode 52 and the first substrate 55.

The first substrate 55 is formed from a material having light transmissibility. The second substrate 56 may have light transmissibility. The first substrate 55 and the second substrate 56 are bonded together by the sealing material 59 that is disposed so as to surround the periphery of the organic EL element. The first substrate 55, the second substrate 56, and the sealing material 59 form an encapsulated structure encapsulating the organic EL element in the interior. The first substrate 55 and/or the second substrate 56 are gas barrier materials in many cases.

As a material for forming any one or both of the first substrate 55 and the second substrate 56, an inorganic material such as glass, or a known transparent resin such as an acrylic resin can be used. A laminated film according to the present embodiment as described above can also be employed as these members.

The first substrate 55 and the second substrate 56, for which the laminated film according to the present embodiment can be employed, correspond to display members or gas barrier materials according to the present embodiment. An organic EL device 50 having such a first substrate 55 and a second substrate 56 has excellent flexibility because the laminated film according to the present embodiment is employed.

The touch sensor 70 has a substrate 71 (touch sensor base material), and an element layer 72 having a detection element formed on the substrate 71.

The substrate 71 is formed by a material having light transmissibility. As the substrate 71, an inorganic material such as glass, or a known transparent resin such as an acrylic resin can be used. The laminated film according to the present embodiment as described above can also be employed as the substrate 71.

In the element layer 72, a known detection element composed of a semiconductor element, wiring, resistors, and the like is formed. Regarding the configuration of the detection element, a configuration that realizes a known detection system, such as a matrix switch, a resistant film system, or a capacitance type, can be employed.

The substrate 71 that can employ the laminated film according to the present embodiment corresponds to an optical member according to the present embodiment. The touch sensor 70 having such a substrate 71 has excellent flexibility because the touch sensor 70 employs the laminated film according to the present embodiment.

The front plate 90 is formed from a material having light transmissibility. The front plate 90 is located at the outermost layer on the display screen side of a display device, and functions as a protective member that protects the display device. The front plate is also referred to as a window film. As the front plate 90, an inorganic material such as glass, or a known transparent resin such as an acrylic resin can be used. A laminated film according to the present embodiment as described above can also be employed as the front plate 90. In a case in which a laminated film is employed as the front plate 90, the laminated film is usually disposed in a direction in which the functional layer is located on the outer side of the display device.

The front plate 90 that can employ a laminated film according to the present embodiment corresponds to an optical member according to the present embodiment. Such a front plate 90 has excellent flexibility because the front plate 90 employs the laminated film according to the present embodiment.

When a display device 100 employs the laminated film according to the present embodiment as one or more constituent members selected from an organic EL device 50, a touch sensor 70 and a front plate 90, the display device 100 can have generally excellent flexibility. That is, the display device 100 can be a flexible device.

The apparatus to which the laminated film according to the present embodiment can be applied (flexible device) is not limited to the display device described above. For example, the laminated film can also be employed in a solar cell having a substrate on which a photoelectric conversion element is formed; and a front plate provided on the substrate surface. In this case, when the laminated film according to the present embodiment is employed as the substrate or the front plate of a solar cell, the solar cell can have generally excellent flexibility.

### EXAMPLES

Hereinafter, the present invention will be described more specifically by way of Examples and Comparative Examples; however, the present invention is not limited to the following Examples.

—Study 1—

### Example 1

A resin film containing a polyimide and silica particles (silica particles content: 60% by mass) was produced as follows according to a known document (for example, United States Patent; U.S. Pat. No. 8,207,256 B2).

Into a polymerization tank that had been purged with nitrogen, an acid anhydride of formula (1), diamines of formula (2) and formula (3), a catalyst, and solvents (γ-butyrolactone and dimethylacetamide) were introduced. The feed amounts were set to 75.0 g of the acid anhydride of formula (1), 36.5 g of the diamine of formula (2), 76.4 g of the diamine of formula (3), 1.5 g of the catalyst, 438.4 g of γ-butyrolactone, and 313.1 g of dimethylacetamide. The molar ratio between the diamine of formula (2) and the diamine of formula (3) was 3:7, and the molar ratio between the sum of diamines and the acid anhydride was 1.00:1.02.

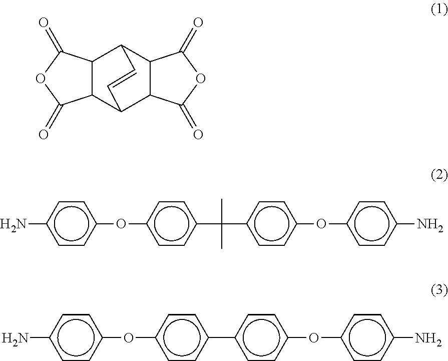

The mixture in the polymerization tank was stirred, and the raw materials were dissolved in the solvents. Subsequently, the mixture was heated to 100° C., and then was heated to 200° C. The mixture was kept at the temperature for 4 hours, and thus a polyimide was polymerized. During this heating, water in the liquid was eliminated. Subsequently, a polyimide was obtained through purification and drying.

Next, a γ-butyrolactone solution of the polyimide that had been adjusted to a concentration of 20% by mass, a dispersion liquid obtained by dispersing silica particles in γ-butyrolactone at a solid content concentration of 30% by mass, and a dimethylacetamide solution of an alkoxysilane having an amino group were mixed, and the mixture was stirred for 30 minutes.

Here, the mass ratio between the silica particles and the polyimide was set to 60:40, and the amount of the alkoxysilane having an amino group was set to 1.67 parts by mass with respect to 100 parts by mass of the sum of the silica particles and the polyimide.

The mixed solution was applied on a glass substrate and was heated for 30 minutes at 50° C. and for 10 minutes at 140° C., and thus the solvent was dried. Subsequently, a film was peeled off from the glass substrate, a metal frame was attached to the film, and the film was heated for one hour at 210° C. Thus, a resin film having a thickness of 80 μm was obtained.

A two-liquid curable type primer (trade name: ARACOAT AP2510, manufactured by Arakawa Chemical Industries, Ltd.) was applied on one surface of the resin film thus obtained, and a coating film was formed. The coating film was dried and cured, and thus a primer layer having a thickness of 1 μm was formed. Next, a solution for forming a functional layer was applied on the primer layer, and thus a coating film was formed. The coating film was dried and cured, and thus a functional layer (layer having functions of surface hardness and ultraviolet absorption) having a thickness of 10 μm was formed. Thus, a laminated film of Example 1 was obtained. The solution for forming a functional layer was prepared by mixing 47.5 parts by mass of a tetrafunctional acrylate (trade name: A-TMMT, manufactured by Shin Nakamura Chemical Co., Ltd.), 47.5 parts by mass of a trifunctional acrylate (trade name: A-TMPT, manufactured by Shin Nakamura Chemical Co., Ltd.), 12.5 parts by mass of a reactive urethane polymer (trade name: 8BR-600, manufactured by Taisei Fine Chemical Co., Ltd., 40 mass % product), 3 parts by mass of a triazine-based ultraviolet absorber (TINUVIN (registered trademark) 479, manufactured by BASF SE), 8 parts by mass of a photopolymerization initiator (IRGACURE (registered trademark) 184, manufactured by Ciba Specialty Chemicals, Inc.), 0.6 parts by mass of a leveling agent (trade name: BYK-350, manufactured by BYK Chemie Japan K.K.), and 107 parts by mass of methyl ethyl ketone, and stirring the mixture.

### Comparative Example 1

On one principal face of a base material (PMMA film) having a thickness of 120 μm and formed from polymethyl methacrylate (PMMA), a functional layer having a thickness of 10 μm was formed in the same manner as in Example 1. Thus, a laminated film of Comparative Example 1 was obtained.

(Evaluation) Measurement of Pencil Hardness

The pencil hardness of the surface on the functional layer side of the laminated films of Example 1 and Comparative Example 1 was measured according to JIS K5600-5-4. The load for the measurement of pencil hardness was set to 1 kg. The results are presented in Table 1.

Evaluation of Flexibility

The laminated films of Example 1 and Comparative Example 1 were cut to a size of 1 cm×8 cm. Each of the laminated films after cutting was wound on a roll having a radius of r=1 mm, with the functional layer surface of the laminated film being put on the inner side, and the presence or absence of cracking in the laminated film was checked. Flexibility was judged according to the following criteria. The results are presented in Table 1.

A: Cracking did not occur, and satisfactory external appearance was maintained.

C: Five or more cracks were generated.

Optical Characteristic Degree of Yellowness (YI Value)

The degrees of yellowness (Yellow Index: YI value) of the laminated films of Example 1 and Comparative Example 1 were measured by means of an ultraviolet/visible/near-infrared spectrophotometer, V-670, manufactured by JASCO Corp. Background measurement was performed in a state without any sample, subsequently a laminated film was placed on a sample holder, and measurement of transmittance for light at 300 nm to 800 nm was performed. Thus, tristimulus values (X, Y, Z) were determined. The YI value was calculated based on the equation described below.

YI value=100×(1.28X−1.06Z)/Y

The optical characteristics were judged according to the following criteria. The results are presented in Table 1.

A: The YI value is less than 3.

C: The YI value is 3 or greater.

Transmittance

Transmittance for light at 300 nm to 800 nm was measured using an ultraviolet/visible/near-infrared spectrophotometer, V-670, manufactured by JASCO Corp. The transmittance was judged according to the following criteria. The results are presented in Table 1.

A: The transmittance for light having a wavelength of 550 nm is 90% or higher.

B: The transmittance for light having a wavelength of 550 nm is lower than 90%.

Haze

A laminated film was placed on a sample holder, and the haze of the laminated film was measured by means of a fully automated direct-reading haze computer, HGM-2DP, manufactured by Suga Test Instruments Co., Ltd. The haze was judged according to the following criteria. The results are presented in Table 1.

A: The haze (%) is less than 1.0%.

C: The haze (%) is 1.0% or higher.

Ultraviolet Deterioration Acceleration Test (QUV Test, Light Irradiation Test)

A laminated film was subjected to a QUV test using a UVCON manufactured by Atras Material Testing Solutions GmbH. The light source was UV-B 313 nm, the output power was 40 W, and the distance between the sample (laminated film) and the light source was set to 5 cm. The laminated film was irradiated with ultraviolet radiation for 24 hours from the functional layer side.

After the irradiation with ultraviolet radiation, optical characteristics (YI value and transmittance) were evaluated as described above. The results are presented in Table 1.

TABLE 1

| | | | Optical | | | | |
|---|---|---|---|---|---|---|---|
| | | | characteristics | | | QUV test | |
| | Pencil | | YI | | | YI | |
| | hardness | Flexibility | value | Haze | Transmittance | value | Transmittance |
| Ex. 1 | 3H | A | A | A | A | A | A |
| Comp. | 3H | C | A | A | A | A | A |
| Ex. 1 | | | | | | | |

From the results of Table 1, the laminated film of Example 1 has excellent flexibility. In addition, it was found that the laminated film of Example 1 has functional properties such as ultraviolet-resistant characteristics and surface hardness, and can be used for an optical member, a display member, and a front plate of flexible devices.

—Study 2—

### Example 2

A γ-butyrolactone solution of polyimide adjusted to a concentration of 20% by mass was prepared using a polyimide similar to that of Example 1. This solution, a solution in which silica particles were dispersed in γ-butyrolactone at a solid content concentration of 30% by mass, a dimethylacetamide solution of an alkoxysilane having an amino group, and water were mixed, and the mixture was stirred for 30 minutes.

Here, the mass ratio of silica particles and the polyimide was set to 60:40, the amount of the alkoxysilane having an amino group was set to 1.67 parts by mass with respect to 100 parts by mass of the sum of the silica particles and the polyimide, and the amount of water was set to 10 parts by mass with respect to 100 parts by mass of the sum of the silica and the polyimide.

Using the mixed solution thus obtained, and a laminated film having a resin film, a primer layer, and a functional layer, in which these were laminated in this order, was obtained in the same manner as in Example 1. However, the thickness of the functional layer was changed to 6 μm.

### Example 3

A polyimide having a glass transition temperature of 390° C. (“NEOPULIM” manufactured by Mitsubishi Gas Chemical Co., Inc.) was prepared. A γ-butyrolactone solution of this polyimide at a concentration of 20% by mass, a dispersion liquid in which silica particles were dispersed in γ-butyrolactone at a solid content concentration of 30% by mass, a dimethylacetamide solution of an alkoxysilane having an amino group, and water were mixed, and the mixture was stirred for 30 minutes. Thus, a mixed solution was obtained. The mass ratio of the silica particles and the polyimide was 55:45, the amount of the alkoxysilane having an amino group was 1.67 parts by mass with respect to 100 parts by mass of the sum of the silica particles and the polyimide, and the amount of water was 10 parts by mass with respect to 100 parts by mass of the sum of the silica particles and the polyimide. Using this mixed solution, a laminated film of Example 3 having a resin film, a primer layer, and a functional layer (thickness 10 μm), in which these were laminated in this order, was obtained in the same manner as in Example 1.

### Comparative Example 2

The resin film of Example 2 in a state before the primer layer and the functional layer were formed was evaluated as a film of Comparative Example 2.

(Evaluation) Optical Characteristics

The films of Example 2 and Comparative Example 2 were subjected to a QUV test (light irradiation test) similar to that of Study 1. For the films before and after the test, transmittance, YI value, and haze were measured in the same manner as in Study 1. The difference between the YI values before and after the test, ΔYI, was also determined. The results are presented in Table 2.

Visibility

A film before a light irradiation test was bent, and the external appearance state such as contrast and color at that time was checked. Visibility was judged according to the following criteria. The results are presented in Table 2.

A: Any change in contrast and color was not recognized.

C: A change in the external appearance such as changes in contrast and color was recognized.

TABLE 2

| | Before light irradiation | | | After light irradiation | | | |
|---|---|---|---|---|---|---|---|
| | test | | | test | | | |
| | Transmittance | | Haze | | | Haze | |
| | [%] | YI value | [%] | Transmittance | ΔYI | [%] | Visibility |
| Ex. 2 | 92.7 | 2.3 | 0.9 | 92.0 | 0.8 | 0.9 | A |
| Ex. 3 | 90.1 | 1.4 | 0.8 | 89.6 | 0.5 | 0.8 | A |
| Comp. | 90.4 | 1.9 | 0.7 | 84.3 | 11.7 | 1.0 | C |
| Ex. 2 | | | | | | | |

As shown in Table 2, the laminated film of Example 2 that had been subjected to a light irradiation test satisfied the above-described conditions (i) and (ii), and it was confirmed that this laminated film has high visibility upon bending.

—Study 3—

### Example 4

A resin film containing a polyimide and silica particles and having a thickness of 75 μm (silica particles content 60% by mass) was produced in the same manner as in Example 1.

One principal face of the resin film was subjected to a UV ozone treatment. The UV ozone treatment was performed for 15 minutes using an ultraviolet (UV) ozone cleaning apparatus, UV-208, manufactured by Technovision, Inc.

Next, a silane coupling agent having an amino group (3-aminopropyltriethoxysilane, trade name: Z6011, manufactured by Dow Corning Toray Co., Ltd.) was applied on one principal face that had been subjected to the UV ozone treatment of the resin film, and thus a primer layer was formed.

Next, a solution for forming a functional layer was applied on the primer layer, and a coating film was formed. The coating film was dried and cured, and thereby a functional layer (layer having functions of surface hardness and ultraviolet absorption) having a thickness of 5 μm was formed. Thus, a laminated film of Example 3 was obtained. The solution for forming a functional layer was prepared by mixing 47.5 parts by mass of a tetrafunctional acrylate (trade name: A-TMMT, manufactured by Shin Nakamura Chemical Co., Ltd.), 47.5 parts by mass of a trifunctional acrylate (trade name: A-TMPT, manufactured by Shin Nakamura Chemical Co., Ltd.), 12.5 parts by mass of a reactive urethane polymer (trade name: 8BR-600, manufactured by Taisei Fine Chemical Co., Ltd., 40 mass % product), 3 parts by mass of a triazine-based ultraviolet absorber (TINUVIN (registered trademark) 479, manufactured by BASF SE), 8 parts by mass of a photopolymerization initiator (IRACURE (registered trademark) 184, manufactured by Ciba Specialty Chemicals, Inc.), 0.6 parts by mass of a leveling agent (trade name: BYK-350, manufactured by BYK Chemie Japan K.K.), and 107 parts by mass of methyl ethyl ketone, and stirring the mixture.

### Reference Example

A resin film containing a polyimide and silica particles and having a thickness of 75 μm (silica particles content 60% by mass) was produced in the same manner as in Example 1.

Next, a silane coupling agent having an amino group (3-aminopropyltriethoxysilane, trade name: Z6011, manufactured by Dow Coming Toray Co., Ltd.) was applied on one principal face of the resin film, and thus a primer layer was formed.

Next, a functional layer similar to that of Example 3 was formed on the primer layer, and thus a laminated film of Reference Example was obtained.

Evaluation of Surface Composition of Resin Film

The surface that had been subjected to a UV ozone treatment in the resin film of Example 3, and one principal face of the resin film of Reference Example were evaluated by X-ray photoelectron spectroscopy (XPS).

For the X-ray photoelectron spectroscopy, an X-ray photoelectron spectroscopic apparatus (trade name: QUANTERA SXM, manufactured by U1vac-PHI, Inc.) was used. For X-radiation, A1Ka (1486.6 eV) having a diameter of 100 μm was used. For the purpose of charge compensation, an electron gun of 1 eV and an Ar ion gun of 10 eV were used. The photoelectron take-off angle was set to 75°.

From an XPS spectrum obtained by using an analysis software: MULTIPAK V8.2C attached to the apparatus, peak areas of each element were determined, and the amounts of the each element at the film surface were calculated, expressed in atom%, from the peak areas. Furthermore, the atomic ratio of silicon atoms with respect to nitrogen atoms (Si/N) was calculated from the Si2p peaks and N1s peaks. The results are presented in Table 3.

Haze

The haze (%) of the laminated film was evaluated by a method similar to that in Study 1. The results are presented in Table 4.

TABLE 3

| | C1s | N1s | O1s | Si2p | Si/N |
|---|---|---|---|---|---|
| Ex. 4 | 22 | 2.3 | 56 | 19 | 8.3 |
| Ref. Ex. | 50 | 2.0 | 35 | 13 | 6.5 |

(Unit: atm %)

TABLE 4

| | Haze |
|---|---|
| Ex. 4 | A |
| Ref. Ex. | A |

As shown in Table 3, at the surface that had been subjected to the UV ozone treatment in the resin film of Example 4, Si/N, which is the ratio between silicon atoms and nitrogen atoms, was 8.3. Meanwhile, it was found that Si/N was 6.5 at one surface of the resin film of Reference Example.

Evaluation of Adhesiveness of Functional Layer

Adhesiveness of the functional layers in the laminated films of Examples and Reference Example was evaluated by a crosshatch test according to JIS K5600-5-6. Cuts were inserted in a 10×10 bedrock grids at an interval of 2 mm, and CELLOTAPE (registered trademark, manufactured by Nichiban Co., Ltd.) was attached thereto. The CELLOTAPE was peeled by pulling in a direction of 60° with respect to the surface, and the number of bedrock grids remaining thereafter was counted. Adhesiveness was judged according to the following criteria. The results are presented in Table 3.

A: The number of remaining checker grids was 100.

C: The number of remaining checker grids was 99 or less.

TABLE 5

| | Evaluation of adhesiveness |
|---|---|
| Ex. 4 | A |
| Ref. Ex. | C |

From the results of Table 5, it was found that in the laminated film of Example 4, adhesiveness of the functional layer was high, and in the laminated film of Reference Example, adhesiveness of the functional layer was low.

### REFERENCE SIGNS LIST

10: Resin film, 20: Functional layer, 25: Primer layer, 30: Laminated film, 50: Organic EL device, 70: Touch sensor, 90: Front plate, 100: Display device.

1. A laminated film comprising:
a resin film containing a polyimide-based polymer; and
a functional layer provided on at least one principal face of the resin film.

2. The laminated film according to claim 1, wherein the resin film further includes a silicon material containing silicon atoms.

3. The laminated film according to claim 2, wherein the silicon material is silica particles.

4. The laminated film according to claim 1, wherein when a light irradiation test of irradiating the laminated film with light at 313 nm for 24 hours from the functional layer side by means of a light source having an output power of 40 W that is provided at a distance of 5 cm from the laminated film is performed, the laminated film satisfies the following conditions:
(i) the laminated film after the light irradiation test has a transmittance of 85% or higher for light at 550 nm; and
(ii) the laminated film before the light irradiation test has a degree of yellowness of 5 or less, and the difference between the degrees of yellowness of the laminated film before and after the light irradiation test is less than 2.5.

5. The laminated film according to claim 4, wherein the laminated film after the light irradiation test has a haze of 1.0% or less.

6. A resin film comprising:
a polyimide-based polymer and a silicon material containing silicon atoms,
wherein Si/N that is the atom ratio between silicon atoms and nitrogen atoms is 8 or higher in at least one principal face.

7. The resin film according to claim 6, wherein the silicon material is silica particles.

8. A laminated film comprising:
the resin film according to claim 6; and
a functional layer provided on a principal side of the resin film where Si/N is 8 or greater.

9. The laminated film according to claim 1, wherein the functional layer is a layer having at least one function selected from the group consisting of ultraviolet absorption, surface hardness, tacky adhesiveness, color adjustment, and refractive index adjustment.

10. The laminated film according to claim 1, wherein the functional layer is a layer having at least one function of ultraviolet absorption or surface hardness.

11. The laminated film according to claim 1, further comprising a primer layer that is provided between the resin film and the functional layer.

12. The laminated film according to claim 11, wherein the primer layer includes a silane coupling agent.

13. The laminated film according to claim 12, wherein the silane coupling agent has at least one substituent selected from the group consisting of a methacryl group, an acryl group, and an amino group.

14. A method for producing a laminated film, the method comprising:
a step of applying a UV ozone treatment to at least one principal face of a resin film containing a polyimide-based polymer and a silicon material containing silicon atoms; and
a step of providing a functional layer on the principal face side that has been subjected to the UV ozone treatment of the resin film.

15. An optical member comprising the laminated film according to claim 1.

16. A display member comprising the laminated film according to claim 1.

17. A front plate comprising the laminated film according to claim 1.

18. The laminated film according to claim 8, wherein the functional layer is a layer having at least one function selected from the group consisting of ultraviolet absorption, surface hardness, tacky adhesiveness, color adjustment, and refractive index adjustment.

19. The laminated film according to claim 8, wherein the functional layer is a layer having at least one function of ultraviolet absorption or surface hardness.

20. The laminated film according to claim 8, further comprising a primer layer that is provided between the resin film and the functional layer.

21. An optical member comprising the laminated film according to claim 8.

22. A display member comprising the laminated film according to claim 8.

23. A front plate comprising the laminated film according to claim 8.
